(19) United States
(12) Patent Application Publication
(10) Pub. No.: US 2023/0021906 A1
(43) Pub. Date: Jan. 26, 2023

(54) SELF-MODIFYING AND SELF-IMPROVING SYSTEMS AND METHODS FOR BUILDING, EVALUATING AND RATING PHYSICAL OR VIRTUAL SPACE LAYOUTS

(71) Applicant: Olivier Fischer, Madeira, OH (US)

(72) Inventor: Olivier Fischer, Madeira, OH (US)

(73) Assignee: Olivier Fischer, Madeira, OH (US)

(21) Appl. No.: 17/868,624

(22) Filed: Jul. 19, 2022

Related U.S. Application Data
(60) Provisional application No. 63/225,728, filed on Jul. 26, 2021.

(51) Int. Cl. G06F 30/13; G06F 30/27

(52) U.S. Cl. CPC G06F 30/13; G06F 30/27

(57) ABSTRACT

The disclosed technology is a system that uses an interactive software to help event-organizers customize a virtual layout of a space. The system is an interactive apparatus that allows users to prepare their space by positioning items and properties in the space, and provides the user with constructive feedback in a plurality of areas, thus assisting event-organizers in sufficient planning and design. The system uses machine learning to improve its performance and the quality of its feedback to users overtime. Such a technology will provide effective physical arrangement and accommodate successful event preparation.

### RELATED APPLICATIONS

This application claims the priority of U.S. Provisional Patent App. 63/225,728, filed Jul. 26 2021, and titled SELF MODIFYING AND SELF IMPROVING SYSTEMS AND METHODS FOR BUILDING, EVALUATING AND RATING PHYSICAL OR VIRTUAL SPACE LAYOUTS, the disclosure of which is incorporated herein by reference.

### FIELD

The disclosed technology pertains to an interactive system for the customization and presentation of a virtual layout of a space, wherein properties and items can be placed in the space to make it useful for a specific purpose. The disclosed technology allows a user to virtually place properties and items in a desired space, and provides the user with feedback with respect to several aspects of their layout. The aspects of this feedback include but are not limited to: sustainability, security, cost, visibility, cleanliness, and convenience.

### BACKGROUND

There exists a segment of event-organizers that utilize software, methods, apparatuses, or programs to prepare layout and construction of properties and items in a physical space. These systems are not typically accompanied by any sort of internal assessment or feedback communication to ensure the user effectively constructs a sufficient event or that the system can learn and improve its performance over time. These programs are not designed to self-evaluate the associated sustainability, cost, cleanliness, or other parameters of the user's virtual layout.

What is needed, therefore, is an improved system for event-organizers to assist the user in optimizing their event space by providing helpful feedback with respect to a plurality of attributes. An accessible and sophisticated software that assesses and communicates with the user can enhance the way event-organizers design the physical space of their event. The feedback can also be used by the system itself to learn and improve over time.

### BRIEF DESCRIPTION OF THE DRAWINGS

The drawings and detailed description that follow are intended to be merely illustrative and are not intended to limit the scope of the invention as contemplated by the inventors.

FIG. 1 is a schematic diagram of an exemplary system configured to connect a server hub (100) to a plurality of user devices (110, 120, 130).

FIG. 2 is a flowchart of a set of steps that a system could perform to allow a user to create an event.

FIG. 3 is a flowchart of a set of steps that a system could perform to allow a user to insert an item in their virtual layout.

FIG. 4 is a flowchart of a set of steps that a system could perform to allow a user to effectively navigate the toolbar of the program.

FIG. 5 is a flowchart of a set of steps that a system could perform to allow a user to save their map.

FIG. 6 is a screenshot of an interface usable to users of the software.

FIG. 7 is another screenshot of an interface usable to users of the software.

### DETAILED DESCRIPTION

The inventors have conceived of novel technology that, for the purpose of illustration, is disclosed herein as applied in the context of systems that allow users to virtually design events in physical spaces. While the disclosed applications of the inventors' technology satisfy a long-felt but unmet need in the art of software dedicated to virtual event-planning, it should be understood that the inventors' technology is not limited to being implemented in the precise manners set forth herein, but could be implemented in other manners without undue experimentation by those of ordinary skill in the art in light of this disclosure. Accordingly, the examples set forth herein should be understood as being illustrative only, and should not be treated as limiting.

Various non-limiting embodiments of the present disclosure will be described to provide an overall understanding of the principles of the events layout software system described herein. The examples discussed herein are examples only and are provided to assist in the explanation of the apparatuses, devices, systems, and methods described herein. None of the features or components shown in the drawings or discussed below should be taken as mandatory for any specific implementation of any of these apparatuses, devices, systems, or methods unless specifically designated as mandatory.

In this disclosure, any identification of specific techniques or arrangements is either related to a specific example presented or is merely a general description of such a technique or arrangement. Identifications of specific details or examples should not be construed as mandatory or limiting unless specifically designated as such. Any failure to specifically describe a combination or sub-combination of components should not be understood as an indication that any combination or sub-combination is not possible.

It will be appreciated that modifications to the disclosed and described examples, arrangements, configurations, components, elements, apparatuses, devices, systems, methods, etc. can be made and may be desired for a specific application. For any methods described, regardless of whether the method is described in conjunction with a flow diagram, it should be understood that, unless otherwise specified or required by context, any explicit or implicit ordering of steps performed in the execution of a method does not imply that those steps must be performed in the order presented but, instead, may be performed in a different order or in parallel.

Throughout this disclosure, references to components or modules generally refer to items that can be grouped logically together to perform a function or group of related functions. Components and modules can be implemented in software, hardware, or a combination of software and hardware. The term “software” is used expansively to include not only executable code, for example machine-executable or machine-interpretable instructions, but also data structures, data stores and computing instructions stored in any suitable electronic format, including firmware, and embedded software.

The present disclosure generally relates to systems, apparatuses, devices, and methods for representations of a space—physical or virtual—its properties, and items that can be placed in the space to make it useful for a specific purpose. In accordance with the present disclosure, the events layout software can also include a set of requirements and rules. These can be based on a combination of physical restrictions or requirements, best practices, and rules and regulations, for example. The rules and regulations can change based on the location and governing jurisdiction, in some embodiments.

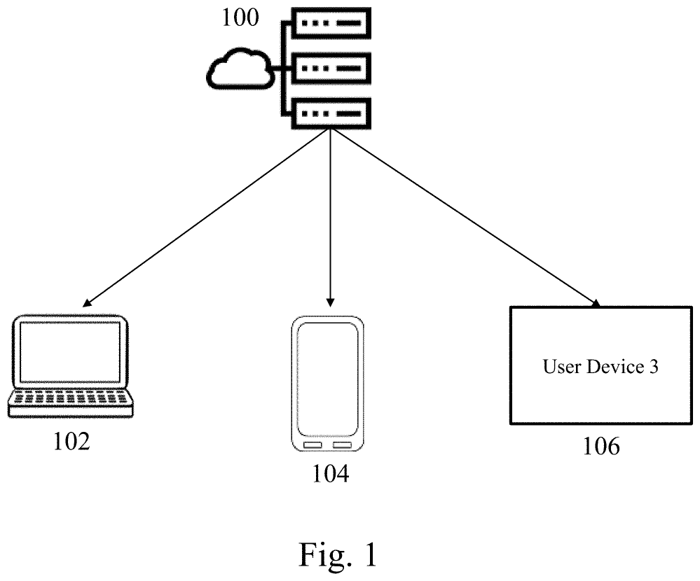

Turning now to the figures, FIG. 1 shows a schematic diagram of an exemplary system configured to connect a server hub to a plurality of user devices.

The system may include one or more servers configured to provide the software environment. The one or more servers that provide the software environment may be implemented as physical servers, edge servers, virtual servers, cloud servers, or a combination thereof.

Each server may include or have access to one or more processors, memories, storage device, communication devices, and other components and features as may be required to transmit, receive, store, and manipulate data across a network. Each server in the software environment may be configured to execute instructions in the software environment using one or more processors (e.g., multiple processors or multi-core processors), or using scalable processing resources (e.g., scalable on-demand cloud or virtual computing). Each server in the software environment may be in communication with one or more storage devices, which may include short-term storage and caching, long-term storage on attached physical medium, or scalable storage resources (e.g., scalable on-demand cloud storage, scalable/swappable data center storage).

While providing the software environment, the one or more servers may be configured to interact with pluralities of user devices (e.g., personal computers, smartphones, internet connected smart devices), and various actions performed by the software, and data created or stored by the software may be executed or stored on the one or more servers, the user devices, or both, as will be apparent to those of ordinary skill in the art in light of this disclosure.

A user device (102) implements or is in communication with a server. The user device (102) may be a tablet, smart phone, laptop computer, desktop computer, standalone kiosk, vehicle infotainment system, or other device having similar or sufficient processing, storage, and communication capabilities including, for example, a processor, a memory, a communication device, a display, a user interface, and other features.

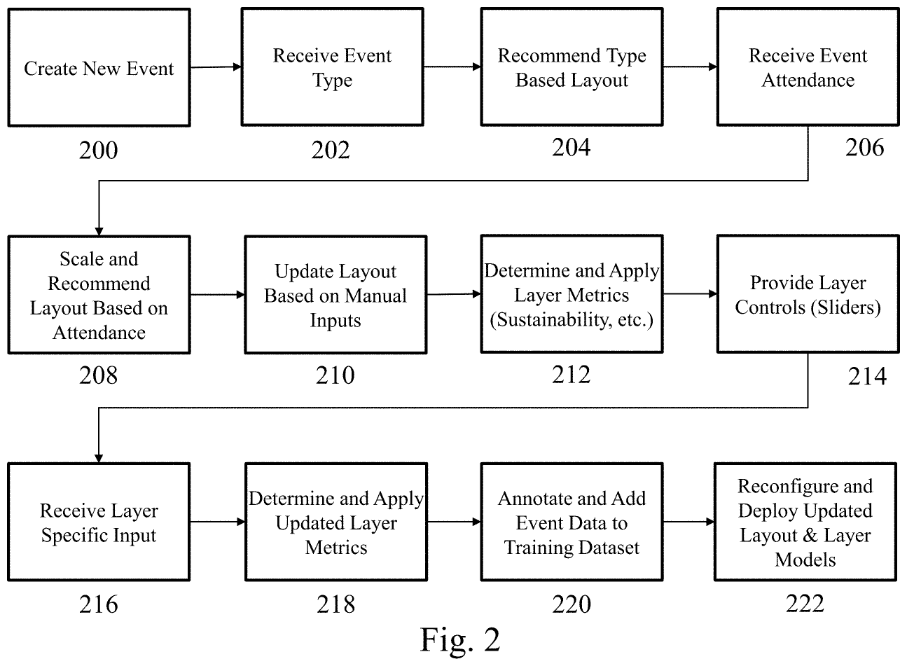

FIG. 2 shows a flowchart that is a set of steps that a system could perform to allow a potential user to create an event with event layers and event layer metrics. Where used herein, “event layer” should be understood to include a combination of underlying data and user interface layer or overlay that communicates the event characteristic to the user, and the “event layer metrics” should be understood to include but are not limited to convenience, accessibility, sustainability, ability, security, cleanliness, cost, and functionality (e.g., a “accessibility layer” may include a graphical overlay on a user interface that highlights, using colors, symbols, or other visual markings, areas of the event space or resources placed within the event space that have high accessibility or low accessibility, based on factors such as width of walking area, availability of ramps or elevators, etc.). First, the user begins the creation of a new event (200) and selects the type of event (202). Then, the system recommends a type of event layout (204). The user then sets the event attendance (206) and the system in response scales the layout of the event (208). Then, the system updates the layout based on a plurality of manual inputs (210), determines and applies a plurality of layer metrics (212). The system then provides a plurality of layer controls, such as sliders, for the user to adjust (214). After receiving layer specific input (216), the system applies updated layer metrics (218), adds event data to a training dataset (220), and reconfigures and deploys an updated layout and layer models (222).

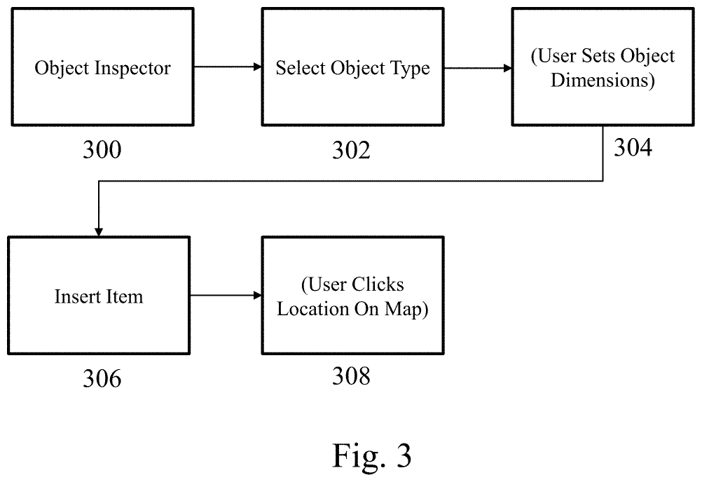

FIG. 3 shows a flowchart that is a set of steps that a system could perform to allow a potential user to insert an item in their virtual layout. These steps include functions for the user to inspect an object (300), select a type of object (302), set the dimensions of the object (304), insert an item (306) and choose a location on the map for the object (308).

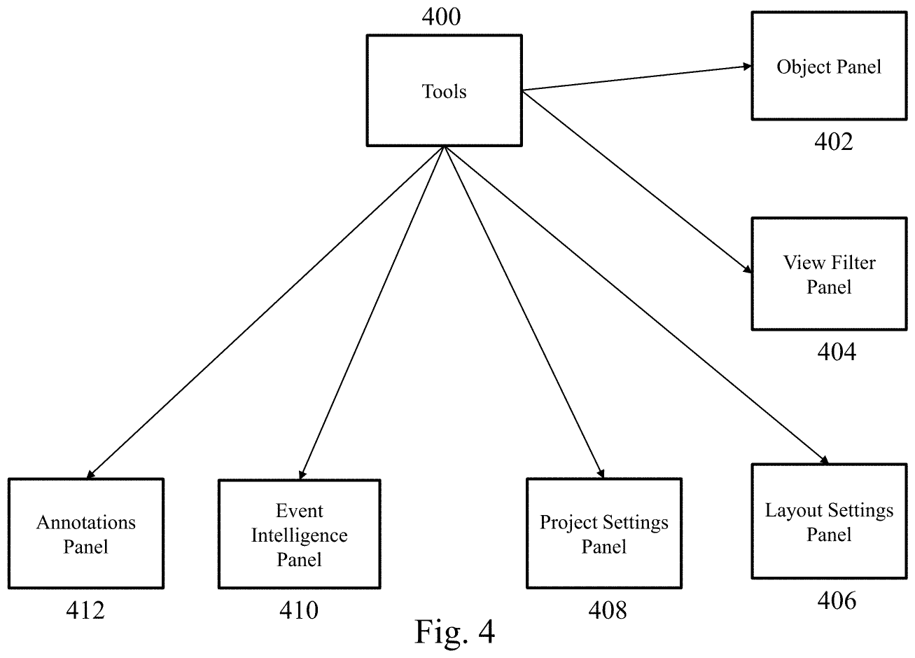

FIG. 4 shows FIG. 3 shows a flowchart that is a set of steps that a system could perform to allow a potential user to effectively navigate the toolbar of the program. The first step entails the user to select the “Tools” tab (400). From there, the user may select from at least the following list of options: Object Panel (402); View Filter Panel (404); Layout Settings Panel (406); Project Settings Panel (408); Event Intelligence Panel (410); and Annotations Panel (412).

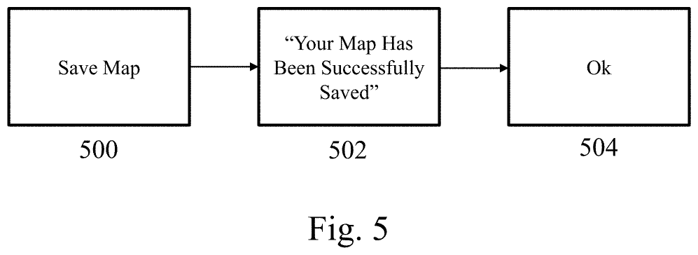

FIG. 5 shows a flowchart that is a set of steps that a system could perform to allow a potential user to save their map. These steps include functions for the user to select “Save Map” (500), receive an output confirming that the map has been saved (502), and clicking “Ok” (504).

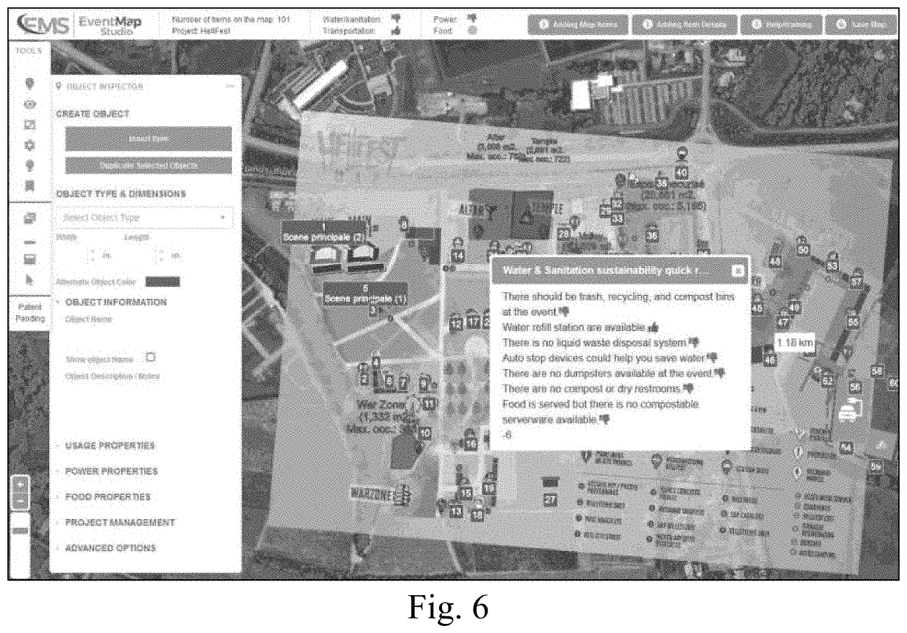

Turning now to FIG. 6, that figure shows a screenshot of an interface usable to users of the software.

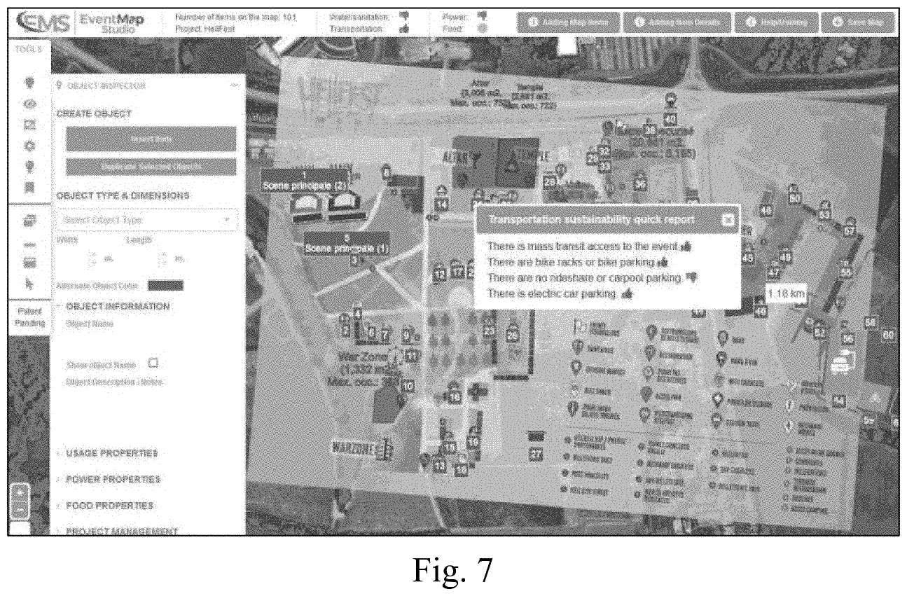

FIG. 7 also shows a screenshot of an interface usable to the users of the software.

For various embodiments, users can either layout items manually, the software can prompt the user on one or more configurations, or the software can automatically place items. Placing an item can be as simple as inserting one tent on the layout. It can also be as complex as placing a group of associated items based on GPS coordinates. Other approaches to laying out items can be utilized. Additionally, or alternatively, placement based on GPS coordinates allows for automation of some or all aspects of the setup and teardown of an event site. It is noted that the systems and methods described herein are not limited to temporary sites as such systems and methods can also be used for permanent sites or structures. Each of the items included as part of the layout may have properties attached to it. These properties can be physical, such as height or color, or more abstract such as use, functionality, sustainability, or security characteristics.

The graphical user display of the events layout system can be accessible through any suitable technique, such as via website or via a specialized application executing on a user computing device, for example. As shown, a user interface can allow for various functionality, such as allowing a user to select object from pre-built or custom list, provide meta-data about object, assign properties to object, and track progress on tasks associated with object. Furthermore, a map of the venue can be provided such that GPS or other geolocational information is incorporated.

With specific reference to the Object Tools, in some embodiments, a user can select from an object menu that is pre-populated based on use. By way of example, if the user is producing a 5K race, objects associated with races (i.e., a finish line) can be provided. Further, pre-populated objects can have data associated with it. By way for example, a concession truck or other waymatic object can have dimensions, weight, and power requirements associated with it. Naming an object and providing a description can pre-populate one or more digital maps. Object Property Tags can automatically generate icons for digital maps. Object Options can allow for tracking tasks associated with objects, or power source for the object. In accordance with some embodiments, based on various data points, a budget is automatically generated based on the layout taking into account pricing in the area. Furthermore, information associated with objects can be aggregated and used to automatically generate RFPs and permits.

In accordance with various embodiments, user movement data can be tracked by the system. Since the GPS coordinates are known for every object, attendees' movements can easily be tracked by GPS on the smartphone or wearable. Other methods—RFID, sound, etc. do not necessarily know the time spent at or the exact location of an attendee. Smartphones in crowds may lose their data connection but GPS is always working. Based on foot traffic, the systems and methods described herein can automatically contact event security via a smartwatch and re-deploy them. Furthermore, in accordance with some embodiments, any staff or attendee can issue an emergency from their smartphone or wearable. The software knows the exact location and can guide emergency services.

The system can be used to evaluate and rate layouts. Evaluation and rating can be done in many different ways and using many sources of information. The evaluation can be manual or automated. The sources of information include but are not limited to rules that are part of the system, the history and evolution of the layouts, manual rating by human experts, or data of things that happened while the realized layout was used such as incidents, theft, or electrical outages. The rating can be expressed in many ways including, but not limited to, a color scale or a numeric value. The numeric value can be an abstract value computed through an algorithm or can be directly linked to a piece of real-world data. For example, the rating could be a numeric value corresponding to the budget necessary to build the layout. In the latter case the highest rating might actually correspond to the lowest budget value. A layout can be rated along many criteria such as sustainability, security, or cost for example.

The data about the layout can be used, with or without rating, as input to a learning system in order to improve the system's knowledge about layouts, and what makes them better or worse. The learning system can be a blackbox, such as a neural network, or a system that associates specific characteristics or combinations of characteristics of layouts to specific event rating or portion of the rating. The learning system will have the goal of maximizing the rating.

It is to be understood that the descriptions of the present invention have been simplified to illustrate elements that are relevant for a clear understanding of the present invention, while eliminating, for purposes of clarity, other elements. Those of ordinary skill in the art will recognize, however, that these sorts of focused discussions would not facilitate a better understanding of the present invention, and therefore, a more detailed description of such elements is not provided herein.

Having shown and described various embodiments of the present invention, further adaptations of the methods and systems described herein may be accomplished by appropriate modifications by one of ordinary skill in the art without departing from the scope of the present invention. Several of such potential modifications have been mentioned, and others will be apparent to those skilled in the art. For instance, the examples, embodiments, geometrics, materials, dimensions, ratios, steps, and the like discussed above are illustrative and are not required. Accordingly, the scope of the present invention should be considered in terms of the following claims and is understood not to be limited to the details of structure and operation shown and described in the specification and drawings.

1. A system comprising:
(a) a management server comprising a processor and a memory;
(b) a user device in communication with the management server and configured to display an event management interface via a display. and receive user inputs via the event management interface;
wherein the processor is configured to:
(i) display a map of an event area, update the map based on user inputs to the event management interface, and display a plurality of selected event resources on locations of the map;
(ii) provide an event layer, wherein the event layer is associated with an event metric, analyze a plurality of event resources to determine a score associated with each event resource, and determine an overall score for that event layer based on the score associated with each event resource, wherein the event metrics comprise one or more of a sustainability metric, a security metric, and an accessibility metric;
(iii) update the event management interface to display the event layer, wherein the event layer comprises an indication of the overall score, and an indication of the score associated with each of the event resources positioned on the map;
(iv) provide a set of layer controls via the event management interface, wherein the set of layer controls are configured to be used by the user to increase or decrease the event metric; and
(v) in response to receiving user inputs and using a machine learning process, modify the event metric, automatically replace one or more of the plurality of selected event resources with an alternate event resource having a different score so that the aggregate event score essentially matches the modified event metric, and update the event management interface to display the modified plurality of selected event resources positioned on the map.
